(19) United States
(12) Patent Application Publication
(10) Pub. No.: US 2010/0002528 A1
(43) Pub. Date: Jan. 7, 2010

(54) SEMICONDUCTOR DEVICE

(75) Inventor: Shinichi OKAWA, Tokyo (JP)

Correspondence Address: MATTINGLY & MALUR, P.C., 1800 DIAGONAL ROAD, SUITE 370, ALEXANDRIA, VA, 22314, US

(73) Assignee: RENESAS TECHNOLOGY CORP., Tokyo (JP)

(21) Appl. No.: 12/433,934

(22) Filed: May 1, 2009

(30) Foreign Application Priority Data
Jul. 1, 2008 (JP) 2008-172142

(51) Int. Cl. G11C 7/00

(52) U.S. Cl. 365/189.06; 365/207

(57) ABSTRACT

A sense amplifier section comprises two stages of latch-type sense amplifier circuits, i.e., a primary-stage latch-type sense amplifier and a secondary-stage latch-type sense amplifier, wherein stress exerted on the primary-stage latch-type sense amplifier is reduced significantly to ensure high accuracy in amplification. In the above configuration including the secondary-stage latch-type sense amplifier, when an amplified output from the primary-stage latch-type sense amplifier reaches a predetermined voltage level (e.g., 50 mV), a transition to amplifying operation of the secondary-stage latch-type sense amplifier is enabled so that a time duration of operation of the primary-stage latch-type sense amplifier (corresponding to a time duration of stress exertion on the primary-stage latch-type sense amplifier) can be shortened significantly. Further, by providing a clamp circuit in the primary-stage latch-type sense amplifier, it is possible to decrease a stress voltage itself to be applied to the primary-stage latch-type sense amplifier.

### CROSS-REFERENCE TO RELATED APPLICATIONS

The disclosure of Japanese Patent Application No. 2008-172142 filed on Jul. 1, 2008 including the specification, drawings and abstract is incorporated herein by reference in its entirety.

### BACKGROUND OF THE INVENTION

The present invention relates to a semiconductor device, and more particularly to a semiconductor device technique effectively applicable to a configuration of a sense amplifier circuit to be used for a semiconductor memory.

The present inventors have examined the following conventional semiconductor device techniques for sense amplifier circuit configurations, for example:

In an SRAM (Static Random Access Memory), for example, a current-mirror-type sense amplifier circuit having a pair of differential amplifier circuits arranged in parallel is used as a sense amplifier circuit for amplifying a minuscule potential difference read out of paired bit lines selected from a memory cell.

Based on results obtained from examinations of the present invention, a prior-art search has been conducted by the present inventors for semiconductor device techniques concerning SRAMs having two stages of sense amplifier circuits. Through this prior-art search, Japanese Unexamined Patent Publications No. 2000-3595 (FIG. 2, FIG. 3, etc.), 2001-273777 (FIG. 3, etc.), and 2001-307488 (FIG. 1, etc.) indicated below were extracted. In Japanese Unexamined Patent Publication No. 2000-3595 (FIG. 2, FIG. 3, etc.), there is disclosed a two-stage circuit configuration comprising a current-mirror-type sense amplifier circuit and a latch-type sense amplifier circuit for performing high-speed amplification with low power consumption. Japanese Unexamined Patent Publication No. 2001-273777 (FIG. 3, etc.) discloses a two-stage circuit configuration comprising two current-mirror-type sense amplifier circuits in which a sense operation is turned off after data setup for reducing power consumption. Japanese Unexamined Patent Publication No. 2001-307488 (FIG. 1, etc.) shows a circuit configuration comprising two current-mirror-type sense amplifier circuits disposed as two stages for providing higher operation speed and further comprising inverting and non-inverting parallel latch circuits for providing independence of data polarities. In Japanese Unexamined Patent Publications No. 2000-3595 (FIG. 2, FIG. 3, etc.), 2001-273777 (FIG. 3, etc.), and 2001-307488 (FIG. 1, etc.), although two-stage configurations of sense amplifier circuits are described, no description is found regarding two-stage configurations of latch-type sense amplifier circuits in particular.

### SUMMARY OF THE INVENTION

The results of examinations by the present inventors on conventional semiconductor device techniques such as mentioned above have revealed the following matters.

For example, in LSIs (Large Scale Integrated circuits) of the 90-nm generation and later, there is a tendency toward increasing characteristic variations of MOS (Metal Oxide Semiconductor) transistors. For memory cells in particular, transistors having minimum dimensions allowable in fabrication processes of each generation are used, giving rise to a considerable problem associated with transistor characteristic variations.

In memory cells of the 90-nm generation, the degree of transistor characteristic variations in a chip has already become larger than that of the predecessors thereof. In circuit design of the 32-nm and 22-nm generations to come, it may become necessary to take account of such possible characteristic variations as to cause an actual read current of a memory cell to decrease to ½ to ⅓ of an intended design current.

In the situation mentioned above, there will arise problems with the sensitivity and accuracy of a sense amplifier. As a read current of a memory cell decreases, a bit line amplitude decreases at input to a sense amplifier. Conventionally, a sense amplifier input on the order of tens of mV has been satisfactory as an requirement for guarantee of proper operation. Henceforth, as regards a sense amplifier input, it will however be required to guarantee proper operation even for a value lower than 10 mV on account of possible occurrence of larger variations in a read current of a memory cell.

In circuit design, a sensitivity level of 10 mV can be achieved without great difficulty. It is possible to achieve this level of sensitivity by providing a certain extent of allowance in sense amplifier operation timing. In the case of memory cells of the 90-nm generation, a sensitivity on the order of mV can be attained by providing a margin of approximately 200 ps.

By way of contrast, it is rather difficult to solve problems with the accuracy of a sense amplifier. The problems with sense amplifier accuracy can be categorized into three kinds. A first kind of problem with sense amplifier accuracy pertains to external noise to be imposed on bit lines, which should be solved in the designing of a memory macro layout and a chip architecture for memory macro implementation.

The term “memory macro” stated above represents a memory operation unit comprising such constituents as a memory cell array containing a plurality of memory cells arranged in a matrix form, an address decoder for selecting a memory cell according to an address signal, a sense amplifier for amplifying data read out of each memory cell, and a write driver for writing data into each memory cell.

In common applications, a plurality of memory macros are distributively provided in a microcomputer, system LSI chip, or the like.

It is to be noted that a memory-dedicated chip as a whole is equivalent to one memory macro.

The above definition of “memory macro” will hereinafter apply unless otherwise specified.

A second kind of problem with sense amplifier accuracy pertains to the designing of a sense amplifier. It is required to address this matter in terms of electrical design and layout topology design. In terms of electrical design, careful consideration should be given to selection of element dimensions and provision of a margin in operation timing. In terms of layout topology design, particular consideration should be given to symmetric arrangements with respect to electrical performance and fabrication process applicability. A third kind of problem with sense amplifier accuracy pertains to element characteristic variations, which can be classified into initial variations and variations with time. While it is possible to reduce initial variations in element characteristics through practices of deliberate designing and testing, there remains difficulty in reducing variations with time in element characteristics.

More specifically, initial variations in element characteristics can be reduced by means of increasing element dimensions or providing symmetrization in layout topology. On the other hand, variations with time represented by NBTI (Negative Bias Temperature Instability), HC (Hot Carrier) or the like cannot be reduced in a manner such as mentioned above. To reduce variations with time in element characteristics, the following two fundamental countermeasures are applicable; provision of a margin in bit line amplitude as a prerequisite, and reduction in stress (mainly voltage stress) exerted on elements.

In MOS transistors, threshold voltage variations due to NBTI or HC are on the order of tens of mV under harsh operating conditions. In the case of a minimum amplitude of 10 mV in design, it is not practical to provide a margin of tens of mV. An response time on bit lines must be increased several-fold, resulting in a significant decrease in memory macro operating speed. Further, under the condition that a variation factor is several times larger than a signal amplitude, problems are prone to occur in design reliability and failure rate level after sale on the market.

In view of the above, to circumvent problems associated with design reliability and failure rate level of products without sacrificing the speed of memory macro operation, it is necessary to decrease stress exerted on elements for reducing characteristic variations with time of a sense amplifier to the order of mV or below.

It is therefore an object of the present invention to provide a semiconductor device technique for reducing characteristic variations with time of a sense amplifier of a memory macro in a semiconductor device to accomplish enhancement in design reliability and reduction in failure rate level after sale on the market.

The above and other objects, features and advantages of the present invention will become more apparent from the following detailed description with reference to the accompanying drawings.

Representative aspects of the preferred embodiments according to the present invention are briefed below.

In the representative aspects of the preferred embodiments of the present invention, there is provided a semiconductor device containing a memory macro that comprises a sense amplifier section having two stages of latch-type sense amplifier circuits, i.e., a primary-stage latch-type sense amplifier and a secondary-stage latch-type sense amplifier, wherein stress exerted on the primary-stage latch-type sense amplifier is reduced significantly to ensure high accuracy in amplification. More specifically, in the above configuration including the secondary-stage latch-type sense amplifier, when an amplified output from the primary-stage latch-type sense amplifier reaches a predetermined voltage level (e.g., 50 mV), a transition to amplifying operation of the secondary-stage latch-type sense amplifier is enabled so that a time duration of operation of the primary-stage latch-type sense amplifier (corresponding to a time duration of stress exertion on the primary-stage latch-type sense amplifier) can be shortened significantly.

Further, by providing a clamp circuit in the primary-stage latch-type sense amplifier, it is possible to decrease a stress voltage itself to be applied to the primary-stage latch-type sense amplifier.

Enumerated below are advantageous effects to be provided according to the representative aspects of the preferred embodiments of the present invention:
(1) In a sense amplifier included in a memory macro, variations with time in characteristics thereof can be reduced to enhance design reliability.
(2) In a two-stage circuit configuration comprising a primary-stage latch-type sense amplifier and a secondary-stage latch-type sense amplifier, a stress voltage and a stress duration are reduced at the primary-stage latch-type sense amplifier to ensure high accuracy in amplification. Thus, characteristic variations with time in the primary-stage latch-type sense amplifier can be reduced.

### BRIEF DESCRIPTION OF THE DRAWINGS

FIG. 1 is a circuit diagram showing a schematic configuration of a memory macro in a semiconductor device according to a preferred embodiment 1 of the present invention;

FIG. 2 is a circuit diagram showing an example of a sense amplifier configuration in the semiconductor device according to the preferred embodiment 1 of the present invention;

FIG. 3 is a waveform chart showing an example of a sense amplifier operation sequence in the semiconductor device according to the preferred embodiment 1 of the present invention;

FIG. 4 is a waveform chart showing an example of another sense amplifier operation sequence in the semiconductor device according to the preferred embodiment 1 of the present invention;

FIG. 5 is a layout pattern diagram showing an example of a sense amplifier configuration in the semiconductor device according to the preferred embodiment 1 of the present invention;

FIG. 6 is a circuit diagram showing an exemplary configuration including a latch-type sense amplifier and a clamp circuit in a semiconductor device according to a preferred embodiment 2 of the present invention;

FIG. 7 is a waveform chart showing an example of a sense amplifier operation sequence in the semiconductor device according to the preferred embodiment 2 of the present invention;

FIG. 8 is a block diagram showing an example of an overall memory macro configuration in the semiconductor device according the preferred embodiment 1 of the present invention; and

FIGS. 9A to 9C are explanatory diagrams each showing an example of a disposition of sense amplifiers and write drivers in a semiconductor device according a preferred embodiment 3 of the present invention.

### DETAILED DESCRIPTION OF THE PREFERRED EMBODIMENTS

The present invention will now be described in detail by way of example with reference to the accompanying drawings showing the preferred embodiments thereof. Throughout the accompanying drawings, like reference characters designate like or corresponding parts to avoid repetitive description thereof. It is to be noted that codes assigned as terminal designations also represent line and signal designations unless otherwise specified, and further represent voltage values in cases associated with power source.

In the following detailed description of the preferred embodiments according to the present invention, some aspects of the present invention are divided into a plurality of sections or a plurality of forms corresponding individual preferred embodiments for the sake of convenience in explanation if necessary. It should be noted, however, that the sections or forms of these aspects divided in the detailed description are mutually related unless otherwise specified, i.e., one section or form of a certain aspect divided in the detailed description is in whole or in part associated with the other sections or forms thereof in such a fashion as a modified embodiment, detailed arrangement, or supplementary implementation. Further, where specific values regarding constituent elements (quantities, ranges and other specific numeric values) are indicated in the following detailed description of the preferred embodiments, it is to be understood that the present invention is not limited to the indicated specific values, and larger or smaller values than the indicated specific values may be applied unless otherwise specified or certainly predefined on the principle of operation.

### Preferred Embodiment 1

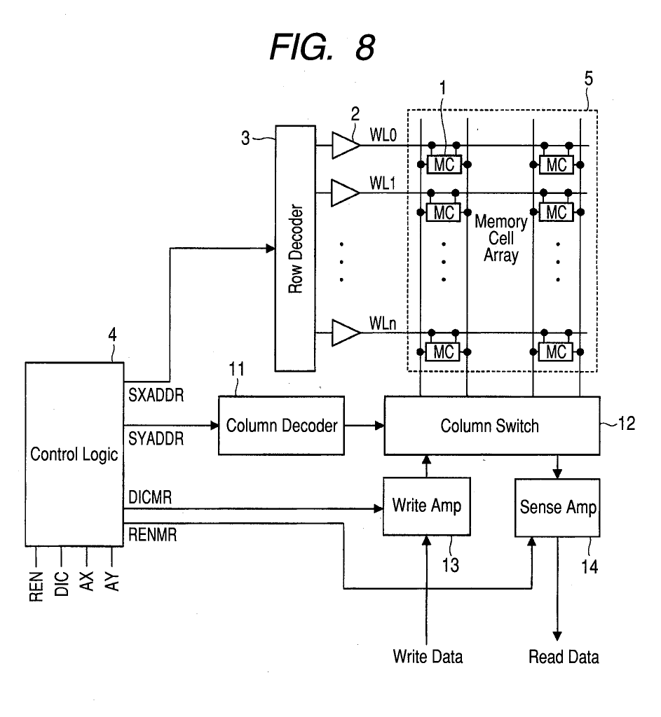

Referring to FIG. 8, there is shown a block diagram of an exemplary overall memory macro configuration in a semiconductor device according to a preferred embodiment 1 of the present invention.

The exemplary overall memory macro configuration in the semiconductor device according to the present preferred embodiment 1 is described below with reference to FIG. 8. The semiconductor device according to the present preferred embodiment 1 is formed particularly, though not exclusively, over a semiconductor substrate such as a silicon substrate by using publicly known techniques for semiconductor integrated circuit fabrication.

According to the present preferred embodiment 1, a memory macro comprises the following components, for example; a memory cell array 5 containing a plurality of static memory cells (MC) 1 arranged in a matrix form, a plurality of word drivers 2 for driving word lines WL0 to WLn coupled to selection terminals of the memory cells 1, a row decoder 3, a control logic circuit 4 for controlling SRAM module write/read operations, a column decoder 11, a column switch 12, a write amplifier 13, a sense amplifier 14, etc. The arrangement mentioned above corresponds to one memory macro unit (memory operation unit), and a plurality of memory macros are distributively provided in a microcomputer or a system LSI chip in common applications.

The selection terminals of the memory cells 1 are coupled row-wise to the word lines WL0 to WLn, and input/output terminals of the memory cells 1 are coupled column-wise to complementary bit lines. Each of the complementary bit lines are coupled to the column switch 12.

Through the control logic circuit 4, address selection signals AX and AY are input to the row decoder 3 and the column decoder 11, respectively, for decoding operations. An output from the row decoder 3 is input to the word driver 2 concerned to activate one of the word lines WL0 to WLn.

On the other hand, an output from the column decoder 11 is input to the column switch 12, so that a pair of the complementary bit lines in the memory cell array 5 is brought into conduction with the write amplifier 13/sense amplifier 14.

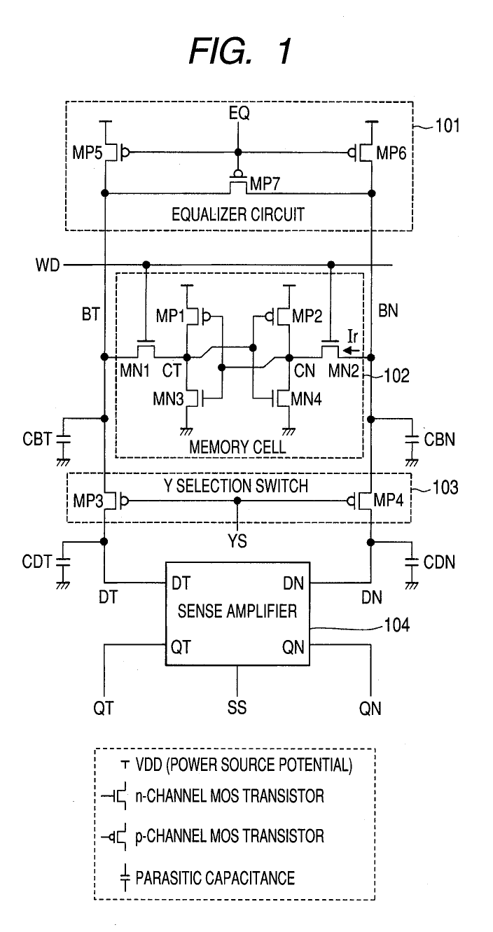

Referring to FIG. 1, there is shown a circuit diagram of a schematic memory macro configuration in the semiconductor device according to the present preferred embodiment 1. In FIG. 1, only a portion associated with memory cell read operations is illustrated as an equivalent circuit. It is to be noted that, in FIG. 1, a memory cell 102 corresponds to the memory cell (MC) 1 indicated in FIG. 8, a Y selection switch 103 corresponds to the column switch 12 indicated in FIG. 8, a sense amplifier 104 corresponds to the sense amplifier 14 indicated in FIG. 8, and a word line WD corresponds to one of the word lines WL0 to WLn indicated in FIG. 8. For the sake of convenience in illustration, such a component as the memory cell 102 or the sense amplifier 104 is indicated as a single item in FIG. 1. In actuality, a plurality of memory cells 102 are arranged in a matrix form, and a plurality of sense amplifiers 104 are arrayed for a plurality of bit lines respectively. In each of the circuit diagrams to be referred to hereinbelow, there is shown only an equivalent circuit corresponding to a portion directly associated with an operation sequence to be performed from the start of transition to an ON state of each memory cell to the end of amplification by each sense amplifier.

With reference to FIG. 1, an exemplary configuration of the semiconductor device according to the present embodiment 1 is described below. The semiconductor device according to the present preferred embodiment 1 is provided, for example, as a semiconductor integrated circuit containing a memory macro, which is formed over a semiconductor chip through such a fabrication process as CMOS (Complementary Metal Oxide Semiconductor) process. The memory cell array in the memory macro comprises the following components, for example; an equalizer circuit 101 for pre-charging a bit line pair BT/BN for potential equalization thereof, a plurality of memory cells 102 arranged in a matrix form in which each memory cell 102 is disposed at an intersection of a word line WD and a bit line pair BT/BN, a sense amplifier 104 for sensing and amplifying a potential difference produced on each bit line pair BT/BN in a read from each memory cell 102, a Y selection switch 103 for coupling between one of bit line pairs BT/BN and a data line pair DT/DN of the sense amplifier 104, etc.

The equalizer circuit 101 comprises p-channel MOS transistors MP5, MP6, and MP7. The sources of the p-channel MOS transistors MP5 and MP6 are each coupled to VDD (power source potential), and the drains of the p-channel MOS transistors MP5 and MP6 are coupled to the bit line pair BT/BN and also to the source and drain of the p-channel MOS transistor MP7 respectively. Each of the gates of the p-channel MOS transistors MP5, MP6, and MP7 is coupled to a line of signal EQ.

The memory cell 102 comprises p-channel MOS transistors MP1 and MP2, and n-channel MOS transistors MN1 to MN4. The p-channel MOS transistor MP1 and the n-channel MOS transistor MN3 are disposed to form an inverter circuit, and the p-channel MOS transistor MP2 and the n-channel MOS transistor MN4 are disposed to form another inverter circuit. These inverter circuits are complementarily coupled to each other through internal terminals CT and CN thereof to provide a latch for storing data. By the n-channel MOS transistors MN1 and MN2, the memory cell 102 is coupled to or decoupled from the bit line pair BT/BN to perform a data write/read operation. Each of the n-channel MOS transistors MN1 and MN2 is coupled to the word line WD. The bit line pair BT/BN contains parasitic capacitance CBT and CBN.

The Y selection switch 103 comprises p-channel transistors MP3 and MP4. The sources and drains of the p-channel MOS transistors MP3 and MP4 are coupled to the bit line pair BT/BN and the data line pair BT/DN. The gates of the p-channel MOS transistors MP3 and MP4 are coupled to a line of signal YS, and the bit line pair BT/BN and the data line pair DT/DN are coupled to or decoupled from each other by the signal YS. The data line pair DT/DN contains parasitic capacitance CDT and CDN.

Then, a memory cell read operation in the semiconductor device according to the present embodiment 1 is described below with reference to FIG. 1. In the following description, a sequence from the rise of a signal on the word line WD to the end of amplification by the sense amplifier 104 is explained while omitting operations of selecting the memory cell 102 and writing data thereinto.

First, the EQ, YS, and word line WD signals are changed over. When the signal EQ turns to VDD (power source potential) from 0 V, the p-channel transistors MP5, MP6 and MP7 included in the equalizer circuit 101 turn off to make the bit line pair BT/BN ready to read data out of the memory cell 102. In this ready-to-read state, the potential on the bit line pair BT/BN is VDD. Then, when the signal YS becomes 0 V, the p-channel transistors MP3 and MP4 included in the Y selection switch 103 turn on, thereby coupling the bit line pair BT/BN and the data line pair DT/DN for input to the sense amplifier 104. When the potential on the word line WD then becomes VDD, the n-channel MOS transistors MN1 and MN2 included in the memory cell 102 turn on. In the memory cell 102, data is retained normally when the potential on either one of the internal terminals CT and CN thereof becomes VDD and the potential on the other one of these terminals becomes 0 V. Herein it is assumed that the potential on the internal terminal CN is 0 V as an initial value. In this case, a read current Ir is fed to the n-channel MOS transistor MN2. Since the read current Ir discharges the parasitic capacitance CBN and CDT, the potential on the bit line BN decreases with a substantially constant slope.

After a lapse of a certain period of time, a sense amplifier start signal SS is changed over. Then, the potential difference on the data line pair DT/DN is amplified by the sense amplifier 104, and the potential on a data output pair QT/QN is developed to levels of 0 V and VDD.

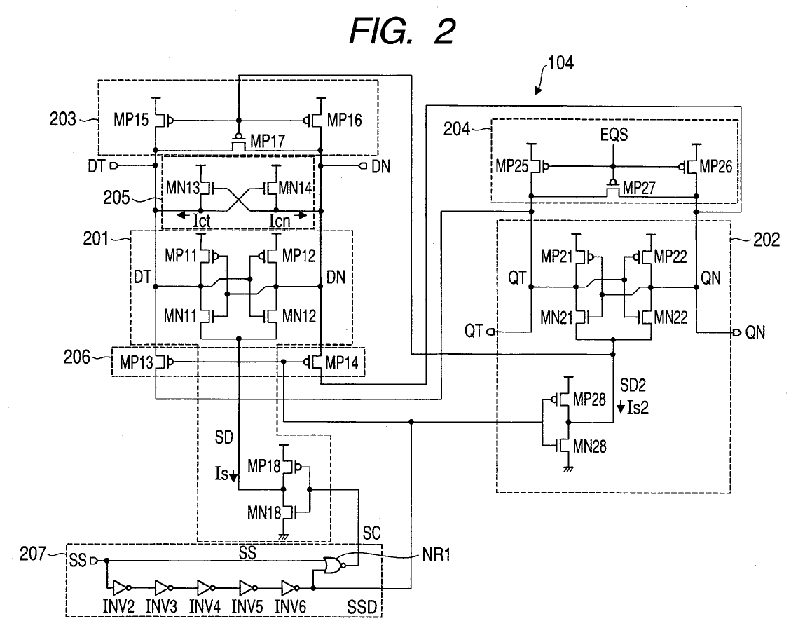

Referring to FIG. 2, there is shown a circuit diagram of an exemplary configuration of the sense amplifier 104 in the semiconductor device according to the present preferred embodiment 1.

As shown in FIG. 2, the sense amplifier 104 comprises a primary-stage latch-type sense amplifier (first latch-type sense amplifier) 201, a secondary-stage latch-type sense amplifier (second latch-type sense amplifier) 202, a primary-stage equalizer circuit 203, a secondary-stage equalizer circuit 204, a clamp circuit 205, a transfer gate pair 206 for coupling or decoupling the latch-type sense amplifiers 201 and 202, a logic circuit 207 for generating operation timing signals for the latch-type sense amplifiers 201 and 202, etc.

The latch-type sense amplifier 201 comprises p-channel MOS transistors MP11, MP12 and MP18, and n-channel MOS transistors MN11, MN12 and MN18. This arrangement serves to provide a latch-type differential amplifier circuit function. The latch-type sense amplifier 202 comprises p-channel MOS transistors MP21, MP22 and MP28, and n-channel MOS transistors MN21, MN22 and MN28. This arrangement also serves to provide a latch-type differential amplifier circuit function. The equalizer circuit 203 comprises p-channel MOS transistors MP15, MP16 and MP17. The equalizer circuit 204 comprises p-channel MOS transistors MP25, MP26 and MP27. The clamp circuit 205 comprises n-channel MOS transistors MN13 and MN14. The clamp circuit 205 serves as a circuit for keeping the potential difference on the data line pair DT/DN below a predetermined voltage level. The transfer gate pair 206 comprises p-channel MOS transistors MP13 and MP14. The logic circuit 207 comprises inverters INV2 to INV6, and a NOR circuit NR1. It is to be noted that the latch-type sense amplifier 201 (first latch-type sense amplifier) and the latch-type sense amplifier 202 (second latch-type sense amplifier) can be decoupled from each other via the transfer gate pair 206, thereby preventing mutual influence for a certain period of time.

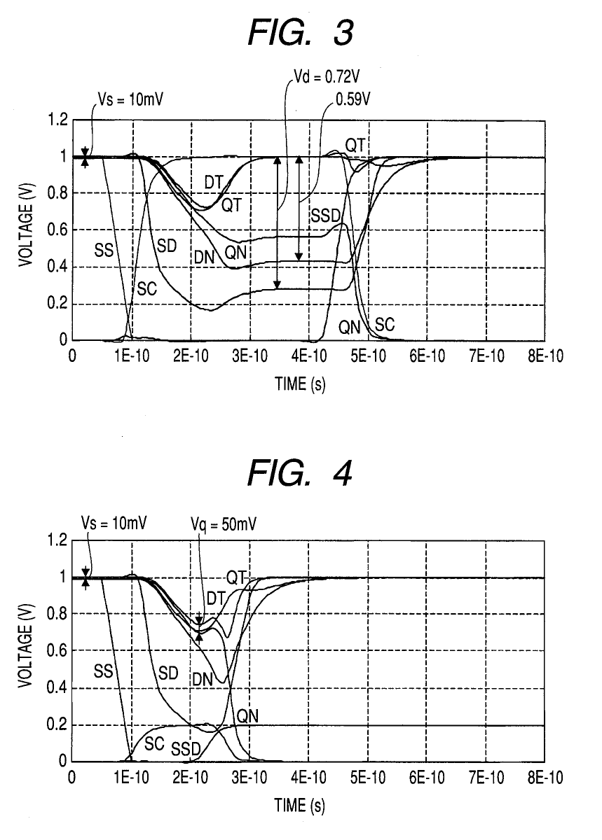

Then, the operations of the sense amplifier 104 are described below with reference to FIGS. 2 and 3. FIG. 3 is a waveform chart showing an exemplary operation sequence of the sense amplifier 104.

In the initial state, the equalizer circuits 203 and 204 remain off. Under this condition, the latch-type sense amplifiers 201 and 202 also remain off, and the potentials of signals SD and SD2 are VDD (power source potential). The p-channel MOS transistors MP13 and MP14 of the transfer gate pair 206 are on. Herein it is preconditioned that, as initial values, the potentials on the data line DT and the data output QT are VDD, and the potentials on the data line DN and the data output QN are VDD-10 mV.

Then, the operations to be performed after sense amplifier startup are described below. When the sense amplifier start signal SS becomes 0 V from VDD, a signal SC goes to VDD from 0 V. The n-channel MOS transistor MN18 then turns on to feed a drive current Is to the n-channel MOS transistors MN11 and MN12. The drive current Is causes the potential on the data line pair DT/DN to decrease, and at the same time, the potential difference thereon (initial value: 10 mV) is widened. When the potential on the data line DN becomes less than 0.6 V, the p-channel MOS transistor MP11 turns on to increase the potential on the data line DT, thereby further widening the potential difference on the data line pair DT/DN.

At this step of sequence in conventional techniques, the potential difference on the data line pair DT/DN is 1 V, and the potential of the signal SD is 0 V. Thus, a stress voltage Vd (Vd=1 V) is applied to the p-channel MOS transistors MP11 and MP12, and the n-channel MOS transistors MN11 and MN12 disposed for amplifying operation in the latch-type sense amplifier 201.

By way of contrast, in the latch-type sense amplifier according to the present preferred embodiment 1, the stress voltage Vd is reduced to 0.72 V as shown in FIG. 3. This advantageous reduction in the stress voltage Vd is attributable to a clamp effect that the n-channel MOS transistors MN13 and MN14 act to stop the widening of potential difference. When the potential difference on the data line pair DT/DN increases beyond a predetermined threshold voltage level of the n-channel MOS transistor MN13/MN14, the n-channel MOS transistor 14 turns on in a case where the data line DT has a higher potential or the n-channel MOS transistor MN13 turns on in a case where the data line DN has a higher potential. Thus, on the data line DT or DN, a decrease of a lower potential is prevented.

As mentioned above, in the semiconductor device according to the present preferred embodiment 1, the primary-stage latch-type sense amplifier for which high accuracy is required is provided with a voltage clamp mechanism. It is thus possible to reduce the stress voltage by approximately 30% as exemplified here.

That is to say, reduction in voltage stress can be brought about by using an n-channel MOS transistor with a drain thereof coupled to a higher-potential-side line of a data line pair.

More specifically, a drain-source voltage on the n-channel MOS transistor MN11 with a drain thereof coupled to the data line DT as shown in FIG. 2 is reduced to 0.72 V as demonstrated in FIG. 3. Thus, the stress voltage in the semiconductor device according to the present preferred embodiment 1 can be made lower than 1 V in conventional arrangements.

Further, reduction in voltage stress can also be brought about by using a p-channel MOS transistor with a drain thereof coupled to a lower-potential-side line of a data line pair.

More specifically, a drain-source voltage on the p-channel MOS transistor MP12 with a drain thereof coupled to the data line DN as shown in FIG. 2 is reduced to 0.59 V as demonstrated in FIG. 3. Thus, the stress voltage in the semiconductor device according to the present preferred embodiment 1 can be made lower than 1 V in conventional arrangements.

Then, the operations to be performed at a changeover from the primary stage to the secondary stage are described below. A signal SSD is an inverted signal of the sense amplifier start signal SS, i.e., through the inverters INV2 to INV6, the sense amplifier start signal SS is delayed and inverted to produce the signal SSD. The following describes the functions of the signal SSD according to the operation sequence thereof.

When the signal SSD goes to a high potential level, the p-channel MOS transistors MP13 and MP14 of the transfer gate pair 206 turn off to decouple the primary stage and the secondary stage from each other. Then, when the signal SD2 goes to a low potential level, the p-channel MOS transistors MP15, MP16 and MP17 of the primary-stage equalizer circuit 203 turn on, and simultaneously the secondary-stage latch-type sense amplifier 202 is activated. Thus, the potential difference on the data output pair QT/QN is developed fully to VDD (power source potential) level.

As another configuration of the transfer gate pair 206 that has been described as comprising the p-channel MOS transistors MP13 and MP14, it may be suggested to provide such a modified arrangement that n-channel MOS transistors are used in combination or p-channel and n-channel MOS transistors are used in combination instead of the p-channel MOS transistors MP13 and MP14. However, it is preferable that only p-channel MOS transistors should be used in combination as in the present preferred embodiment 1. That is, the combination of only p-channel MOS transistors is advantageous since the data line pair DT/DN is precharged to VDD level before sense operation and also a smaller size of circuit configuration is attainable.

Whereas a voltage applied to transistors in the primary-stage latch-type sense amplifier 201 is reduced, a voltage applied to transistors in the secondary-stage latch-type sense amplifier 202 is not reduced as in conventional arrangements. That is, in the secondary-stage latch sense amplifier 202, a voltage corresponding to power source voltage level is applied to transistors thereof.

In the primary-stage latch-type sense amplifier 201, a minuscule voltage on the data line pair DT/DN is sensed, e.g., a potential difference of approximately 10 mV is sensed.

Contrastingly, in the secondary-stage latch-type sense amplifier 202, a voltage amplified by the primary-stage latch-type sense amplifier 201 is sensed, e.g., a potential difference of approximately 50 mV to 100 mV is sensed.

Hence, in the primary-stage latch-type sense amplifier 201, a significantly adverse effect will occur if a transistor threshold voltage deviates even slightly due to voltage stress. As contrasted to this condition, in the secondary-stage latch-type sense amplifier 202 arranged to sense a potential difference larger than that in the primary stage, a larger degree of deviation in threshold voltage due to voltage stress is allowable.

As mentioned above, the latch-type sense amplifiers of the primary and secondary stages are Configured in consideration of functional roles thereof. Thus, as a sense amplifier configuration in total, it is possible to reduce the degree of adverse effect of deviation in threshold voltage due to voltage stress according to the present preferred embodiment 1.

Then, the following describes other advantageous features of the semiconductor device according to the present preferred embodiment 1. In the waveform chart shown in FIG. 3, a rather long interval between the start time points of the primary and secondary stages is demonstrated intentionally in the interest of clarity of the operations of the clamp circuit 205. In actual practice according to the present preferred embodiment 1, the interval between the start time points of the primary and secondary stages can be shortened as shown in FIG. 4.

FIG. 4 is a waveform chart showing another exemplary operation sequence of the sense amplifier 104 in the semiconductor device according to the present preferred embodiment 1. In FIG. 4, the potentials of the signals SC and SSD are indicated on the basis of 0.2 times for the sake of convenience in reading.

In the exemplary operation sequence shown in FIG. 4, when an input potential difference in the secondary-stage latch-type sense amplifier 202 (corresponding to the potential difference on the data output pair QT/QN) reaches 50 mV, the secondary-stage latch-type sense amplifier 202 is started (signal SSD in FIG. 4). In a circuit arrangement in which the secondary-stage latch-type sense amplifier 202 is designed to have an input sensitivity of 50 mV for enabling higher speed of operation, it is possible to significantly shorten a time duration of stress exertion on the primary-stage latch-type sense amplifier 201.

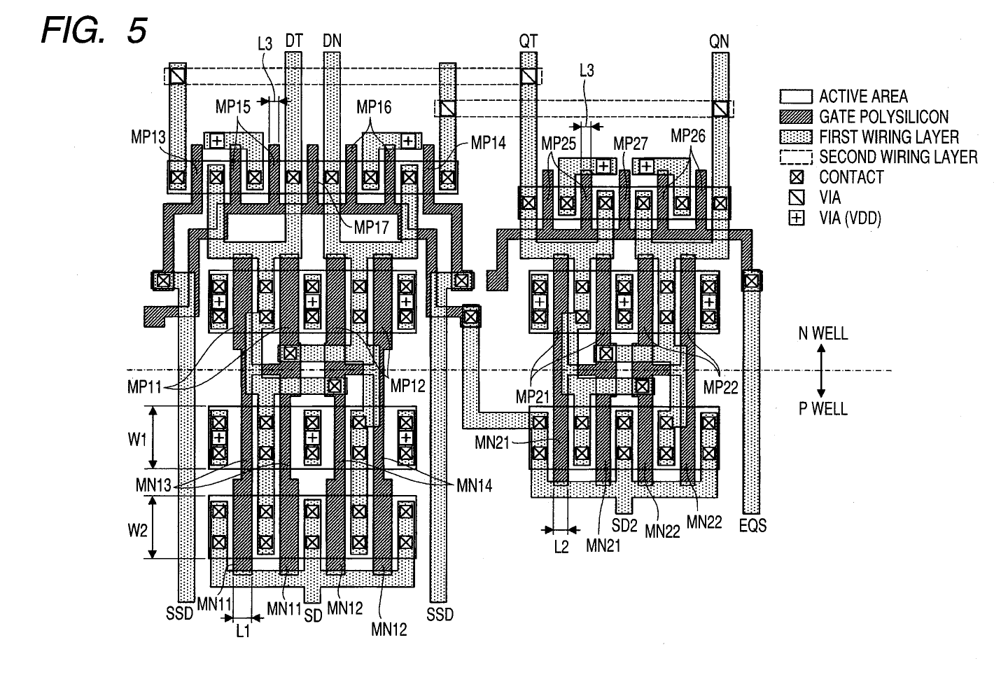

Referring to FIG. 5, there is shown a layout pattern diagram of an exemplary configuration of the sense amplifier 104 in the semiconductor device according to the present preferred embodiment 1.

As shown in FIG. 5, each gate length L1 of the p-channel MOS transistors MP11 and MP12, and the n-channel MOS transistors MN11 and MN12 included in the latch-type sense amplifier 201 is larger than each gate length L2 of the p-channel MOS transistors MP21 and MP22, and the n-channel MOS transistors MN21 and MN22 included in the latch-type sense amplifier 202. Further, the above gate length L2 of the p-channel MOS transistors MP21 and MP22, and the n-channel MOS transistors MN21 and MN22 included in the latch-type sense amplifier 202 is larger than each gate length L3 of n-channel MOS transistors MN13 and MN14 included in the clamp circuit 205, the p-channel MOS transistors MP15 to MP17 included in the equalizer circuit 203, and the p-channel MOS transistors MP25 to MP27 included in the equalizer circuit 204. Since each of the p-channel MOS transistors MP11 and MP12, and the n-channel MOS transistors MN11 and MN12 included in the latch-type sense amplifier 201 has a small signal amplitude (e.g., approximately 10 mV) and senses a minuscule potential difference in amplifying operation, the gate length thereof is relatively large to reduce the degree of adverse effect of characteristic degradation due to voltage stress. Further, since each of the p-channel MOS transistors MP21 and MP22, and the n-channel MOS transistors MN21 and MN22 included in the latch-type sense amplifier 202 senses and amplifies a potential difference (e.g., approximately 50 mV to 100 mV) which is larger than the minuscule potential difference in the latch-type sense amplifier 201, the degree of adverse effect of characteristic degradation due to voltage stress in the latch-type sense amplifier 202 is smaller than that in the latch-type sense amplifier 201. Although the degree of adverse effect due to voltage stress in the latch-type sense amplifier 202 is relatively small, for the purpose of reduction thereof, each gate length of the above MOS transistors included in the latch-type sense amplifier 202 is larger than each gate length of the above MOS transistors included in the clamp circuit 205 and the equalizer circuits 203 and 204.

That is to say, it is preferable that each gate length of the MOS transistors included in the latch-type sense amplifier 201 should be larger than or at least equal to each gate length of the MOS transistors included in the latch-type sense amplifier 202. Further, it is preferable that each gate length of the MOS transistors included in the latch-type sense amplifier 202 should be larger or at least equal to each gate length of the MOS transistors included in the clamp circuit 205 and the equalizer circuits 203 and 204.

In cases where priority is given to stress reduction attributable to the clamp effect, each gate width W1 of the n-channel MOS transistors MN13 and MN14 included in the clamp circuit 205 should be preferably larger than each gate width W2 of the n-channel MOS transistors MN11 and MN12 included in the latch-type sense amplifier 201.

On the other hand, in cases where priority is given to higher speed of sensing operation, the above gate width W2 of the n-channel MOS transistors MN11 and MN12 included in the latch-type sense amplifier 201 should be preferably larger than the above gate width W1 of the n-channel MOS transistors MN13 and MN14 included in the clamp circuit 205.

Therefore, in the semiconductor device according to the present preferred embodiment 1, it is possible to achieve reduction in characteristic variations with time of a sense amplifier section included in a memory macro thereof. As mentioned above, the sense amplifier section comprises two stages of latch-type sense amplifier circuits, wherein a stress voltage and a stress duration are reduced significantly at the primary stage to ensure high accuracy in amplification. Thus, characteristic variations with time in the primary-stage latch-type sense amplifier circuit can be reduced.

### Preferred Embodiment 2

A semiconductor device according to a preferred embodiment 2 of the present invention, which is a modified form of the semiconductor device according to the preferred embodiment 1 described in the foregoing, is intended to enhance the clamp effect for stress reduction.

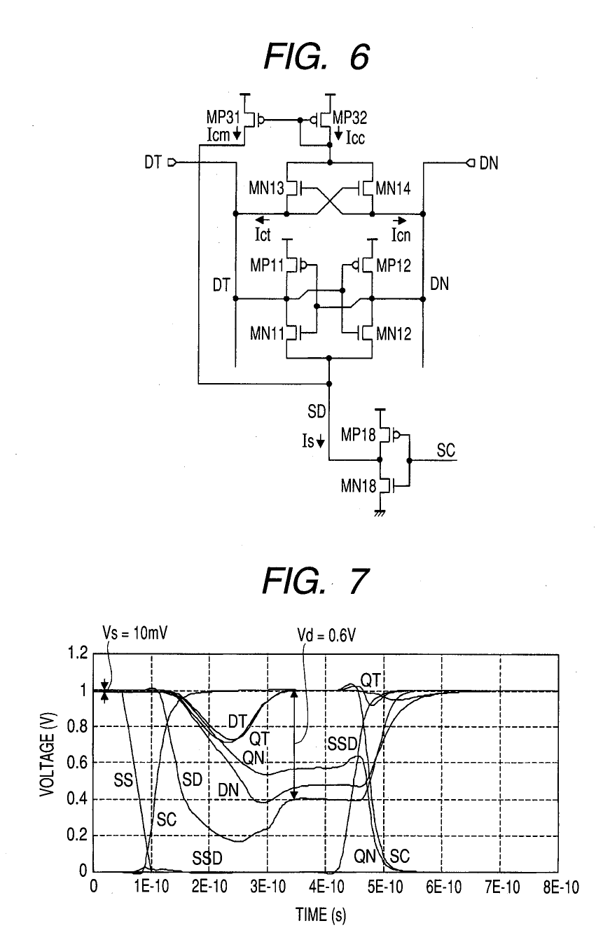

Referring to FIG. 6, there is shown a circuit diagram of an exemplary configuration including a latch-type sense amplifier and a clamp circuit. In FIG. 6, only the latch-type sense amplifier of the primary stage is shown for the sake of convenience in illustration. The arrangements of the other parts are the same as those in the aforementioned preferred embodiment 1, and no repetitive description thereof is given herein.

In the present preferred embodiment 2, p-channel MOS transistors MP31 and MP32 are provided additionally in comparison with the configuration shown in FIG. 2. Further, whereas each drain of the n-channel MOS transistors MN13 and MN14 of the clamp circuit is coupled to VDD in the preferred embodiment 1, the above drain of the n-channel MOS transistors MN13 and MN14 is coupled to the gate and drain of p-channel MOS transistor MP32 in the present preferred embodiment 2. The p-channel MOS transistors MP31 and MP32 are disposed to form a current mirror circuit. The clamp circuit is supplied with either current Ict or Icn, which is fed as a current Icc to the p-channel MOS transistor MP32. A mirror current thereof Icm (to be produced preferably with a multiplying factor of several times) is then applied to a drive current Is. Thus, a part of the drive current Is canceled by the mirror current Icm, resulting in a decrease in the amount of current running to the p-channel MOS transistors MP11 and MP12, and the n-channel MOS transistors MN11 and MN12 included in the latch-type sense amplifier. In this manner, the clamp effect can be enhanced for stress reduction.

Referring to FIG. 7, there is shown a waveform chart of an exemplary sense amplifier operation sequence in the semiconductor device according to the present preferred embodiment 2. As shown in FIG. 7, a stress voltage Vd is reduced to 0.6 V.

Therefore, in the semiconductor device according to the present preferred embodiment 2, the clamp effect can be enhanced in addition to the provision of the same advantageous effects as those demonstrated in the aforementioned preferred embodiment 1.

### Preferred Embodiment 3

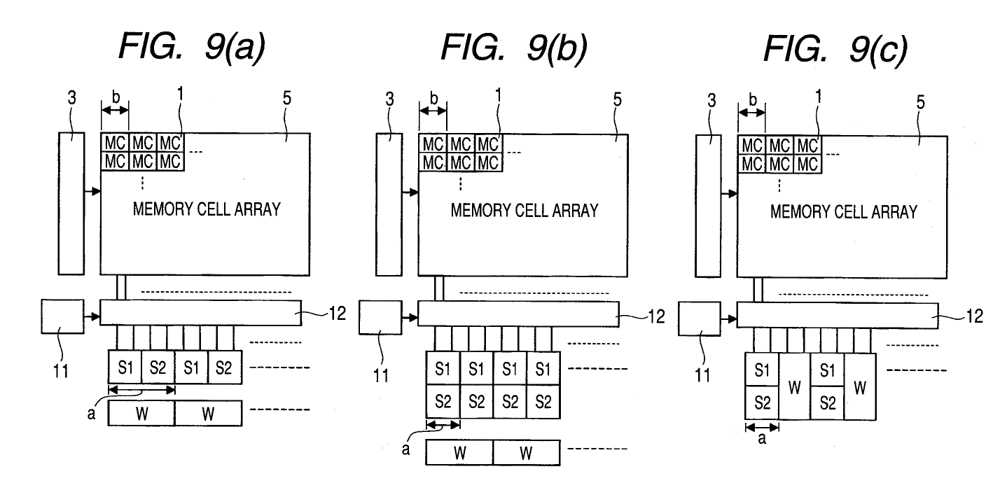

Referring to FIGS. 9A to 9C, there are shown explanatory diagrams of exemplary dispositions of sense amplifiers and write drivers in a semiconductor device according to a preferred embodiment 3 of the present invention. Exemplified in FIGS. 9A to 9C are the dispositions of the sense amplifiers and write drivers according to the aforementioned preferred embodiments 1 and 2.

As shown in FIGS. 9A to 9C, the sense amplifiers and write drivers are provided in correspondence with a plurality rows of memory cells. The layout pattern shown in FIG. 5 corresponds to FIG. 9A.

The arrangements shown in FIGS. 9A and 9C are advantageous in cases where the number of sense amplifiers is relatively small and the sense amplifiers are provided per a relatively large number of columns (e.g., the sense amplifiers are provided per eight rows of memory cells, not per two rows of memory cells).

That is, it is preferable to use the arrangements shown in FIGS. 9A and 9C in cases where there are provided more than a definite number of columns (memory cells, bit lines) and where one of the columns is selected by the column switch for coupling to data lines.

It is to be noted that the above definite number of columns should be determined by the width of the sense amplifier layout indicated as dimension “a” in FIGS. 9A and 9C and the width of the memory cell layout indicated as dimension “b” in FIGS. 9A and 9C.

The arrangement shown in FIG. 9B is advantageous in cases where the number of sense amplifiers is relatively large and the sense amplifiers are provided per a relatively small number of columns (e.g., the sense amplifiers are provided per two rows of memory cells, not per eight rows of memory cells).

That is, it is preferable to use the arrangement shown in FIG. 9B in cases where there are provided less than a definite number of columns (memory cells, bit lines) and where one of the columns is selected by the column switch for coupling to data lines.

As mentioned above, in the configuration comprising two stages of sense amplifiers it is preferable to select a suitable sense amplifier arrangement according to the number of bit lines (columns) to be coupled to each sense amplifier.

While the present invention has been described in detail with respect to specific embodiments thereof, it is to be understood that the present invention is not limited by any of the details of description and that various changes and modifications may be made in the present invention without departing from the spirit and scope thereof.

For example, while the preferred embodiments of the present invention have been described on the assumption that the SRAM is used as a memory macro, it is to be understood that the present invention is not limited thereto and that such memory devices as flash memory, EPROM and DRAM devices are also applicable as memory macros.

Further, while the clamp circuit for keeping an intermediate voltage level by preventing a decrease down to 0 V on the data line pair DT/DN has been demonstrated in the foregoing description, there may be provided such an arrangement that an increase up to a level of power source voltage applied to the sense amplifier is prevented on the data line pair DT/DN. In the preferred embodiments 1 and 2, there may also be provided an arrangement in which an increase up to 1 V is prevented on the data line pair DT/DN.

It is to be noted, however, that a decrease down to 0 V on the data line pair DT/DN should be prevented particularly in cases where bit lines and data lines are precharged to a power source voltage level before read operation.

In the above cases, before read operation, a power source voltage level is already provided on the bit lines and data lines. Hence, an arrangement for preventing a decrease down to 0 V on the data line pair DT/DN is to be provided.

Contrastingly, in cases where bit lines and data lines are precharged to ½ of a power source voltage level or to 0 V before read operation, it is preferable to prevent an increase up to the source voltage level on the data line pair DT/DN.

Further, while the preferred embodiments 1 and 2 have been described on the assumption that the clamp circuit is included, the present invention may also be embodied in such a modified form that reduction in voltage stress is accomplished by controlling the transfer gate pair 206 without the provision of the clamp circuit.

More specifically, in the above modified form, the transfer gate pair 206 of the primary-stage sense amplifier is arranged to decouple the data line pair DT/DN and the data output pair QT/QN from each other before the potential difference on the data line pair DT/DN increases to a power source voltage level.

Thus, it is also possible to reduce voltage stress while eliminating the need for providing the clamp circuit.

As regards industrial applicability of the present invention, the semiconductor device technique according to the present invention is effectively applicable to LSI memory macros using MOS transistors or the like.

What is claimed is:

1. A semiconductor device comprising:
a memory cell;
a bit line pair coupled to the memory cell;
a first latch-type sense amplifier including MOS transistors, the first latch-type sense amplifier being arranged to have a first differential output pair coupled to the bit line pair; and
a second latch-type sense amplifier including MOS transistors, the second latch-type sense amplifier being disposed as a secondary stage posterior to the first latch-type sense amplifier and being arranged to have a second differential output pair for receiving output from the first latch-type sense amplifier;
wherein the first latch-type sense amplifier is supplied with a power source including a first voltage and a ground voltage, and
wherein there is provided a clamp circuit including MOS transistors, the clamp circuit being arranged to provide a function for keeping a potential difference on the first differential output pair within a range of a predetermined potential difference smaller than the difference between the first voltage and the ground voltage.

2. The semiconductor device according to claim 1,
wherein the first differential output pair of the first latch-type sense amplifier is coupled to the second differential output pair of the second latch-type sense amplifier via a transfer gate pair.

3. The semiconductor device according to claim 2,
wherein the second latch-type sense amplifier is started after the transfer gate pair turns off.

4. The semiconductor device according to claim 1,
wherein each gate length of the MOS transistors included in the first latch-type sense amplifier is larger than or equal to each gate length of the MOS transistors included in the second latch-type sense amplifier.

5. The semiconductor device according to claim 4,
wherein each gate length of the MOS transistors included in the second latch-type is larger than or equal to each gate length of the MOS transistors included in the clamp circuit.

6. The semiconductor device according to claim 1,
wherein each gate width of the MOS transistors included in the clamp circuit is larger than each gate width of the MOS transistors included in the first latch-type sense amplifier.

7. The semiconductor device according to claim 1,
wherein each gate width of the MOS transistors included in the first latch-type sense amplifier is larger than each gate width of the MOS transistors included in the clamp circuit.

8. The semiconductor device according to claim 1,
wherein the clamp circuit is provided with a current mirror circuit for reduction in current to be fed to a lower-potential-side line of the first differential output pair.

9. The semiconductor device according to claim 1,
wherein a potential difference on the second differential output pair at the start and end of sense operation of the second latch-type sense amplifier is larger than a potential difference on the first differential output pair at the start and end of sense operation of the first latch-type sense amplifier.

10. A semiconductor device comprising:
a memory cell;
a bit line pair coupled to the memory cell;
a first latch-type sense amplifier including MOS transistors, the first latch-type sense amplifier being arranged to have a first differential output pair coupled to the bit line pair; and
a second latch-type sense amplifier including MOS transistors, the second latch-type sense amplifier being disposed as a secondary stage posterior to the first latch-type sense amplifier and being arranged to have a second differential output pair for receiving output from the first differential output pair of the first latch-type sense amplifier;
wherein the first differential output pair of the first latch-type sense amplifier is coupled to the second differential output pair of the second latch-type sense amplifier via a transfer gate pair.

11. The semiconductor device according to claim 10,
wherein each gate length of the MOS transistors included in the first latch-type sense amplifier is larger than or equal to each gate length of the MOS transistors included in the second latch-type sense amplifier.
